(19) United States
(12) Patent Application Publication
(10) Pub. No.: US 2026/0095146 A1
(43) Pub. Date: Apr. 2, 2026

(54) Elastic Wave Device and Communication Module Including the Elastic Wave Device

(71) Applicant: Sanan Japan Technology Corporation, Tokyo (JP)

(72) Inventors: Kanehisa Kimbara, Tokyo (JP); Shinichi SHIOI, Tokyo (JP)

(21) Appl. No.: 19/340,876

(22) Filed: Sep. 26, 2025

(30) Foreign Application Priority Data
Sep. 27, 2024 (JP) 2024-168220

(51) Int. Cl. H03H 9/08; H03H 9/05; H03H 9/10

(52) U.S. Cl. CPC H03H 9/08; H03H 9/0542; H03H 9/059; H03H 9/1085

(57) ABSTRACT

An elastic wave device is disclosed, which includes a wiring substrate; a device chip mounted on the wiring substrate via a plurality of bumps, the device chip having a resonator; a metal pattern formed in an outer edge portion of the wiring substrate; a plurality of bump pads formed on the wiring substrate and including an antenna pad, a transmission pad, a reception pad, and a ground pad; a solder resist layer bonded to both the metal pattern and the wiring substrate; a sealing portion disposed on the wiring substrate and penetrating between the wiring substrate and the device chip to hermetically seal the device chip; wherein the solder resist layer is bonded to the sealing portion.

### CROSS-REFERENCE TO RELATED APPLICATION

The present disclosure claims priority to Japanese Patent Application No. 2024-168220 filed September 27, 2024, the contents of which are herein incorporated by reference in its entirety.

### FIELD

This application relates to the field of mobile communication devices and, more particularly, to an elastic wave device and a module including the elastic wave device.

### BACKGROUND

In devices such as smartphones, which are exemplified by mobile communication terminals, it is required to support communication in multiple high-frequency bands. Accordingly, a front-end module equipped with a plurality of band-pass filters for communication in high-frequency bands is used.

In addition, elastic wave devices such as band-pass filters, duplexers, and quadplexers are employed in front-end modules.

Patent Document 1 (Japanese Unexamined Patent Publication No. 2019-54354) discloses an example related to an elastic wave device.

In elastic wave devices such as band-pass filters and duplexers, a device chip constituting (e.g., an SAW filter) is mounted on a wiring substrate via flip-chip bonding. In order to cause the resonator constituting the SAW filter to generate mechanical vibration, a cavity needs to be formed, and sealed with a material such as synthetic resin or metal.

Since the resonator of the elastic wave device generates heat due to mechanical vibration and other factors, a package structure with good heat dissipation performance is required. If the heat dissipation is poor, it may lead to deterioration of device characteristics, reduction in power durability life, and other problems.

In addition, in order to prevent moisture from entering the sealed cavity, good adhesion between the sealing portion and the wiring substrate is required. If the adhesion between the sealing portion and the wiring substrate is poor, the internal metal is likely to rust, resulting in deterioration of characteristics or shortening of service life.

Furthermore, in some elastic wave devices, in order to improve adhesion between the sealing portion and the wiring substrate, the metal pattern formed on the outer edge of the wiring substrate is designed to have a serrated shape toward the center of the wiring substrate. In such cases, the sealing resin more easily penetrates between the wiring substrate and the device chip, which significantly increases the likelihood that the resin will come into contact with the resonator portion.

Moreover, between a metal pattern that allows electric signals of a target frequency band to pass and a metal pattern that blocks the target frequency band, care must be taken to avoid coupling or other interference. If coupling occurs, device characteristics will also deteriorate.

### SUMMARY

Some examples described herein may have an object to provide an elastic wave device exhibiting excellent heat dissipation, superior adhesion between the sealing portion and the wiring substrate, effective suppression of coupling between metal patterns carrying target frequency signals and non-signal-carrying metal patterns.

In some examples, an elastic wave device is provided, which comprises a wiring substrate; a device chip mounted on the wiring substrate via a plurality of bumps, the device chip having a resonator; a metal pattern formed in an outer edge portion of the wiring substrate; a plurality of bump pads formed on the wiring substrate and including an antenna pad, a transmission pad, a reception pad, and a ground pad; a solder resist layer bonded to both the metal pattern and the wiring substrate; a sealing portion disposed on the wiring substrate and penetrating between the wiring substrate and the device chip to hermetically seal the device chip; wherein the solder resist layer is bonded to the sealing portion.

In some examples, a communication module includes the above-mentioned elastic wave device.

Details of one or more embodiments of the present application are set forth in the accompanying drawings and the description below. Other features, objects, and advantages of the present application will become apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a cross-sectional view of an elastic wave device 1 disclosed in the embodiment.

FIG. 2 is a schematic diagram showing the configuration of a metal pattern 7 formed on a wiring substrate 3.

FIG. 3 is a schematic diagram showing the configuration of a solder resist layer 10 formed on a wiring substrate 3.

FIG. 4 is another schematic diagram of the configuration of the solder resist layer 10.

FIG. 5 is a diagram for illustrating the configuration of a device chip 5.

FIG. 6 is a plan view showing an embodiment in which the elastic wave element 52 is a surface acoustic wave resonator.

FIG. 7 is a cross-sectional view showing an embodiment in which the elastic wave element 52 is a piezoelectric thin-film resonator.

FIG. 8 is a cross-sectional view of a module 100 according to Embodiment 2 of the present invention.

FIG. 9 is a schematic diagram of the circuit configuration of the module 100.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

FIG. 1 is a cross-sectional view of an elastic wave device 1 according to this embodiment.

As shown in FIG. 1, the elastic wave device 1 according to this embodiment includes a wiring substrate 3 and two device chips 5 mounted on the wiring substrate 3.

In this embodiment, the illustrated elastic wave device is an exemplary duplexer with two mounted device chips 5. However, the present invention is not limited thereto, and the device may also be a band-pass filter type elastic wave device with only one device chip 5 mounted thereon, or a quadruplexer with four device chips 5 mounted thereon. In addition, functional elements that achieve the duplexer function may be formed on a single device chip.

As the wiring substrate 3, for example, a multilayer substrate made of resin or a low-temperature co-fired ceramics (LTCC) multilayer substrate composed of a plurality of dielectric layers may be used. The wiring substrate 3 is also provided with a plurality of external connection terminals 31.

The device chip 5 may employ, for example, a substrate made of a piezoelectric single crystal such as lithium tantalate, lithium niobate, or quartz, or a piezoelectric ceramic.

In addition, the device chip 5 may be a composite substrate formed by bonding a piezoelectric substrate and a support substrate. The support substrate may be, for example, a sapphire substrate, an alumina substrate, a spinel substrate, or a silicon substrate.

On the wiring substrate 3, a metal pattern 7 and a plurality of bump pads 9 are formed. The metal pattern 7 is formed in an outer edge portion of the wiring substrate 3, while the bump pads 9 are formed inward of the metal pattern 7. The metal pattern 7 and the bump pads 9 may be made of, for example, copper or a copper-containing alloy, with a thickness ranging, for example, from 10 μm to 35 μm.

A solder resist layer 10 is formed on the metal pattern 7 and the wiring substrate 3. The solder resist layer 10 may be formed from a material such as thermosetting epoxy resin, with a thickness of, for example, 10 μm to 35 μm. The solder resist layer 10 is formed so as to be bonded to both the metal pattern 7 and the wiring substrate 3.

A sealing portion 17 is formed at a position covering the device chip 5. The sealing portion 17 is made of an insulating material such as synthetic resin, for example, epoxy resin or polyimide, but the material is not limited thereto. Preferably, epoxy resin is used, and the sealing portion 17 is formed by a low-temperature curing process. During the thermosetting process for forming the sealing portion 17, the sealing resin may penetrate between the wiring substrate 3 and the device chip 5. Since the metal pattern 7 is metallic and the sealing portion 17 is resin-based, the bonding between the two is relatively weak, creating a risk that the sealing portion 17 will peel away from the wiring substrate 3. In a conventional wiring substrate without a solder resist layer, the area of the metal pattern 7 has been considerably restricted to ensure sufficient bonding strength. The solder resist layer 10, although made of resin, exhibits good adhesion to the metal pattern 7. Furthermore, since the solder resist layer 10 itself is also made of resin, it also has good adhesion to both the wiring substrate 3 and the sealing portion 17. The adhesive force between the solder resist layer 10 and the metal pattern 7 is high. Accordingly, by providing the solder resist layer 10, restrictions on the area of the metal pattern 7 can be relaxed, and the requirement for peel strength between the wiring substrate 3 and the sealing portion 17 can be reduced, thereby enabling more flexible design.

The device chip 5 is flip-chip mounted on the wiring substrate 3 via bumps 15. The bumps 15 may be, for example, gold bumps. The height of the bumps 15 is, for example, from 20 μm to 50 μm.

The bump pads 9 are electrically connected to the device chip 5 via the bumps 15. Depending on the thickness of the solder resist layer 10 and the height of the bumps 15, the device chip 5 may come into contact with the solder resist layer 10 during bonding. Therefore, as shown in FIG. 1, it is preferable to maintain a distance A of about 50 μm to 100 μm between the solder resist layer 10 and the device chip 5.

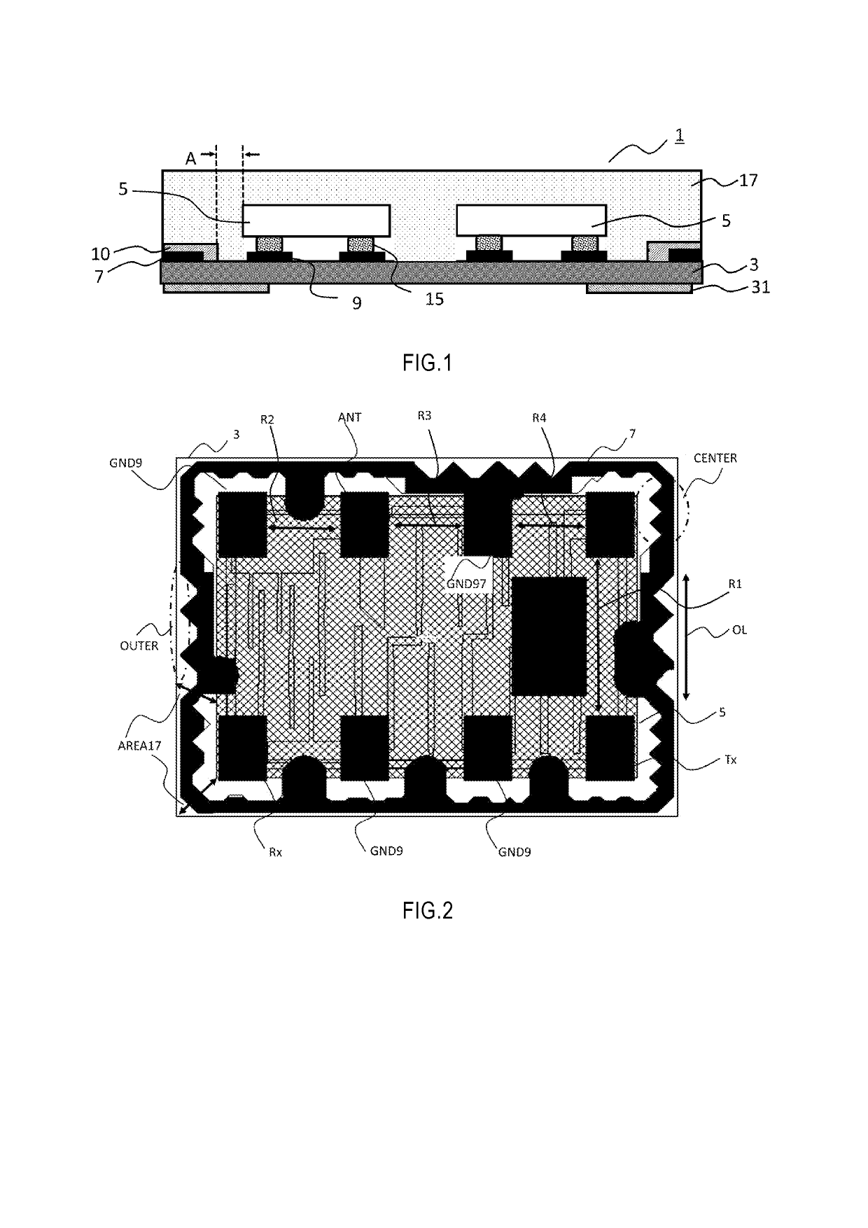

FIG. 2 is a schematic diagram showing the structure of the metal pattern 7 formed on the wiring substrate 3.

As shown in FIG. 2, the metal pattern 7 is formed in an outer edge portion of the wiring substrate 3. The metal pattern 7 has concave–convex shaped portions or serrated shaped portions. In addition, the metal pattern 7 includes a region OUTER, in which the tip direction of the concave–convex shaped portion or the serrated shaped portion is oriented toward the outer edge of the wiring substrate 3, and also includes a region CENTER, in which the tip direction of the concave–convex shaped portion or the serrated shaped portion is oriented toward the center of the wiring substrate 3.

Further, the metal pattern 7 need not be a completely continuous pattern and may include pattern portions having an intermittent structure.

A region AREA17 defined by a solid line representing the outer edge of the wiring substrate 3 and a solid line representing the outer edge of the device chip 5 indicates a bonding region of the sealing portion 17. The bonding region AREA17 of the sealing portion 17 includes a region bonded to the wiring substrate 3 and a region bonded to the metal pattern 7 formed on the wiring substrate 3. That is, the sealing portion 17 (not shown in FIG. 2) is bonded to both the wiring substrate 3 and the metal pattern 7.

The metal pattern 7 enhances thermal conductivity between the wiring substrate 3 and the sealing portion 17, thereby improving the heat dissipation performance of the elastic wave device. In addition, because the boundary between the region where the solder resist layer 10 (not shown in FIG. 2) is bonded to the wiring substrate 3 and the region where the sealing portion 17 is bonded to the metal pattern 7 has a concave–convex or serrated shape, the boundary line becomes longer. Furthermore, in the concave–convex structure, the solder resist layer 10 can extend into the concave portions of the metal pattern 7, and in the serrated structure, the solder resist layer 10 can extend into the valley portions of the metal pattern 7. This structure provides an anchoring effect, thereby improving adhesion between the solder resist layer 10 and the wiring substrate 3.

As shown in FIG. 2, a plurality of bump pads 9 are formed on the wiring substrate 3. The plurality of bump pads 9 include an antenna pad ANT, a transmission pad Tx, a reception pad Rx, and a ground pad GND9. In addition, some bump pads, such as the ground pad GND97, are electrically connected to the metal pattern 7 and serve as ground pads, enhancing grounding performance.

Preferably, in a peripheral region of the antenna pad ANT, the transmission pad Tx, or the reception pad Rx, the tip direction of the concave–convex shaped portion or the serrated shaped portion of the metal pattern 7 is oriented toward the center of the wiring substrate. With this structure, parasitic capacitance between the antenna pad ANT, the transmission pad Tx, or the reception pad Rx and the metal pattern 7 can be limited, and the occurrence of coupling phenomena can be sufficiently suppressed.

As shown in FIG. 2, the wiring substrate 3 has a substantially rectangular structure with long sides and short sides. In a region R1 between two bump pads arranged along the short side direction, the length OL of a region in which the tip direction of the concave–convex shaped portion or the serrated shaped portion of the metal pattern 7 is oriented toward the outer edge of the wiring substrate 3 is greater than the length of a region in which the tip direction is oriented toward the center of the wiring substrate 3.

Since functional elements on the device chip 5 are usually closer to the outer edge along the short side, it is preferable to extend as much as possible the length OL of the region formed toward the outer edge.

During the process of forming the sealing portion 17, the resin that penetrates between the wiring substrate 3 and the device chip 5 may come into contact with functional elements formed on the device chip 5. In the region CENTER, where the tip direction of the concave–convex shaped portion or the serrated shaped portion of the metal pattern 7 is oriented toward the center of the wiring substrate 3, since the metal pattern 7 has a considerable thickness, for example, a thickness of 10 μm to 35 μm, the metal pattern 7 forms a wall surface when pressed during formation of the sealing portion 17, making it easier for sealing resin to penetrate between the wiring substrate 3 and the device chip 5.

Accordingly, for resonators on the device chip 5 located near the region CENTER, it is preferable to form them as far as possible from the outer edge of the device chip 5. Conversely, for resonators on the device chip 5 located near the region OUTER, since the likelihood of sealing resin penetration and contact is lower, it is preferable, from the perspective of space utilization efficiency, to form them closer to the outer edge of the device chip 5.

As shown in FIG. 2, four bump pads are arranged in the long side direction of the wiring substrate 3. As a result, three bump pad interval regions R2, R3, and R4 are formed between them. The region R2 is characterized in that the length of the region in which the tip direction of the concave–convex shaped portion or the serrated shaped portion of the metal pattern 7 is oriented toward the outer edge of the wiring substrate 3 is shorter than the length of the region in which the tip direction is oriented toward the center of the wiring substrate 3.

The regions R3 and R4 are characterized in that the length of the region in which the tip direction of the concave–convex shaped portion or the serrated shaped portion of the metal pattern 7 is oriented toward the outer edge of the wiring substrate 3 is greater than the length of the region in which the tip direction is oriented toward the center of the wiring substrate 3.

The regions R3 and R4 are adjacent to each other, and are two consecutive bump pad interval regions in which the length of the region in which the tip direction of the concave–convex shaped portion or the serrated shaped portion of the metal pattern 7 is oriented toward the outer edge of the wiring substrate 3 is greater than the length of the region in which the tip direction is oriented toward the center of the wiring substrate 3. The bump pad formed between the regions R3 and R4 is a ground pad GND97, which is electrically connected to the metal pattern 7.

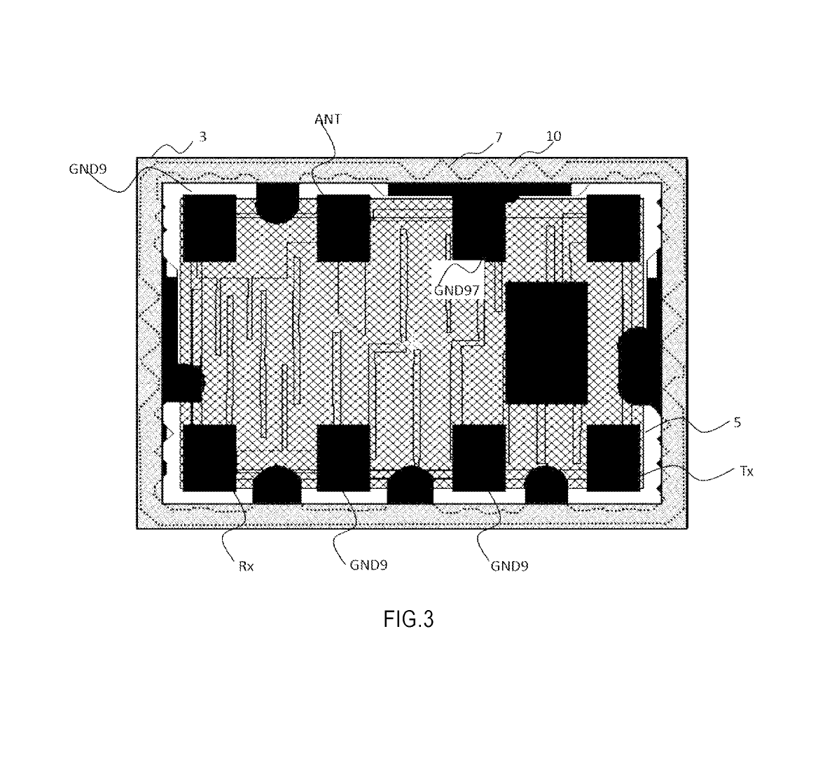

FIG. 3 is a schematic diagram showing the structure of the solder resist layer 10 formed on the wiring substrate 3. FIG. 3 shows a state in which the solder resist layer 10 is provided on the structural example of the metal pattern 7 shown in FIG. 2. Portions of the metal pattern 7 overlapping the solder resist layer 10 are shown by dashed lines. As shown in FIG. 3, the solder resist layer 10 is formed in the outer edge portion of the wiring substrate 3. The solder resist layer 10 includes regions formed directly on the wiring substrate 3 and regions formed on the metal pattern 7.

Preferably, the solder resist layer 10 is made of a solder resist material with good thermal conductivity, preferably ≥1.0 W/m·K, such as the PSR®-4000HS series (registered trademark, available from Taiyo Holdings Co., Ltd.). More preferably, a solder resist material having a thermal conductivity of 3 W/m·K or more is used. For reference, the thermal conductivity of conventional solder resist materials is generally about 0.2 to 0.5 W/m·K.

Preferably, the solder resist layer 10 is made of a solder resist material exhibiting low dielectric characteristics in high-frequency (GHz) bands. For example, the dielectric constant (DK) of the solder resist material at 10 GHz may be 2.0 to 3.0, such as the PSR®-4000 series (registered trademark, available from Taiyo Holdings Co., Ltd.) suitable for substrates for high-frequency components. By comparison, conventional solder resist materials have a dielectric constant DK of about 4.1 to 4.3 in the high-frequency (GHz) bands.

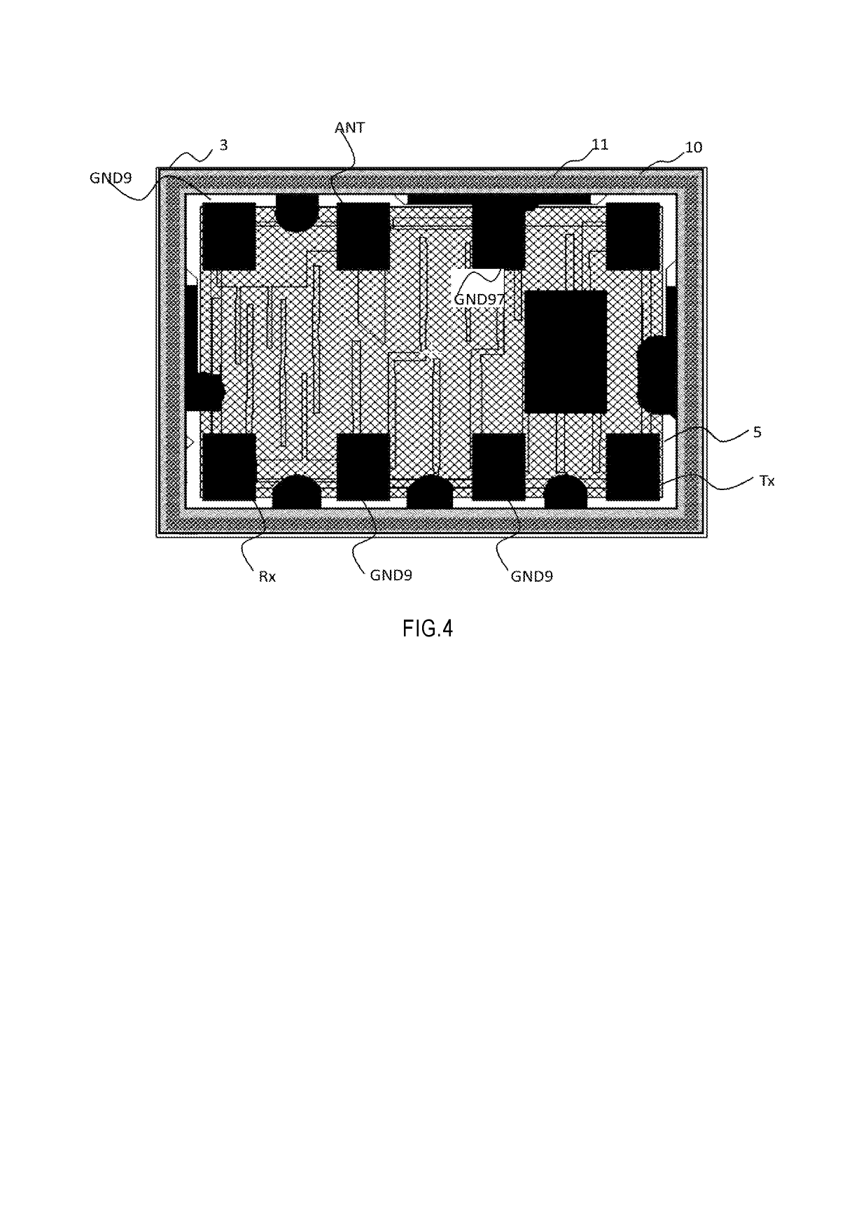

FIG. 4 shows another structural example of the solder resist layer 10. As shown in FIG. 4, it is preferable to subject the solder resist layer 10 to a roughening treatment (forming a roughened portion 11). This treatment can further improve adhesion between the solder resist layer 10 and the sealing portion 17. The roughening treatment may be done mechanically or chemically.

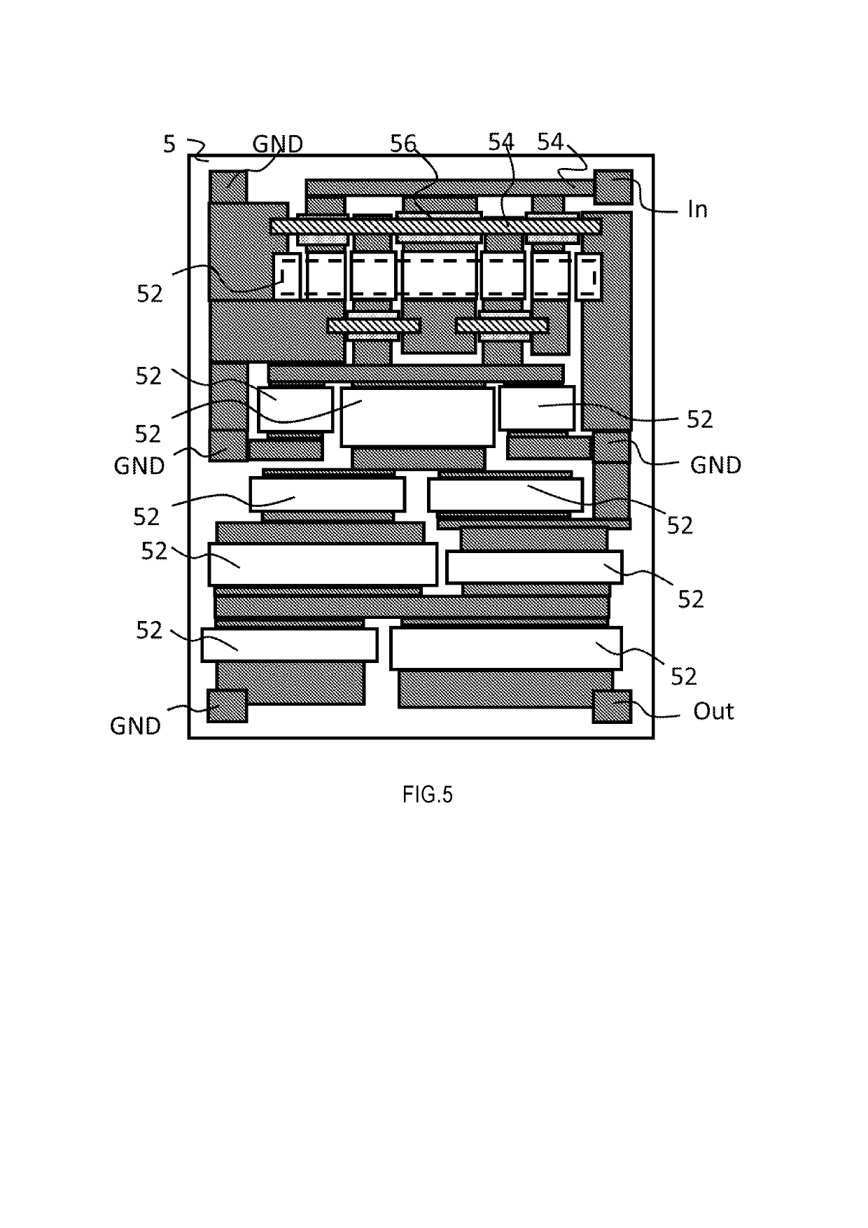

FIG. 5 is a schematic diagram for explaining the structure of the device chip 5.

As shown in FIG. 5, an elastic wave element 52 and a wiring pattern 54 are formed on the device chip 5.

An insulator 56 is formed on the wiring pattern 54. The insulator 56 may be made of, for example, a polyimide material. The insulator 56 may be formed, for example, with a film thickness of 1000 nm.

Another wiring pattern 54 is formed on the insulator 56, and the wiring structure is three-dimensionally constructed so as to spatially cross via the insulator 56.

The elastic wave element 52 and the wiring pattern 54 may be made of a suitable metal or alloy such as silver, aluminum, copper, titanium, or palladium. These metal patterns may also be formed in a laminated structure of multilayer metal films. The thickness of the elastic wave element 52 and the wiring pattern 54 may be set to, for example, 150 nm to 400 nm.

The wiring pattern 54 includes wiring structures constituting an input pad In, an output pad Out, and a ground pad GND. In addition, the wiring pattern 54 is electrically connected to the elastic wave element 52.

As shown in FIG. 5, by forming a plurality of elastic wave elements 52, for example, a band-pass filter can be configured. The band-pass filter is designed to allow only signals of a desired frequency band among the electric signals received at the input pad In to pass through.

The electric signal input from the input pad In is passed through the band-pass filter, and the electric signal in the desired frequency band is output to the output pad Out.

The electric signal output to the output pad Out is output from the external connection terminal 31 on the wiring substrate 3 via the bumps 15 and the bump pads 9.

FIG. 6 is a plan view showing an example in which the elastic wave element 52 is a surface acoustic wave resonator.

As shown in FIG. 6, an IDT (Interdigital Transducer) 52a for exciting surface acoustic waves and reflectors 52b are formed on the device chip 5. The IDT 52a has a pair of comb-shaped electrodes 52c disposed opposite to each other.

The comb-shaped electrodes 52c each have a plurality of electrode fingers 52d and busbars 52e for connecting the plurality of electrode fingers 52d. The reflectors 52b are disposed on both sides of the IDT 52a.

The IDT 52a and the reflectors 52b may be made of an aluminum-copper alloy, with a thickness of 150 nm to 400 nm.

The IDT 52a and the reflectors 52b may also include other metals such as titanium, palladium, silver, or other suitable metals or their alloys, or may be made of these alloys. In addition, the IDT 52a and the reflectors 52b may be formed in a laminated structure of multilayer metal films.

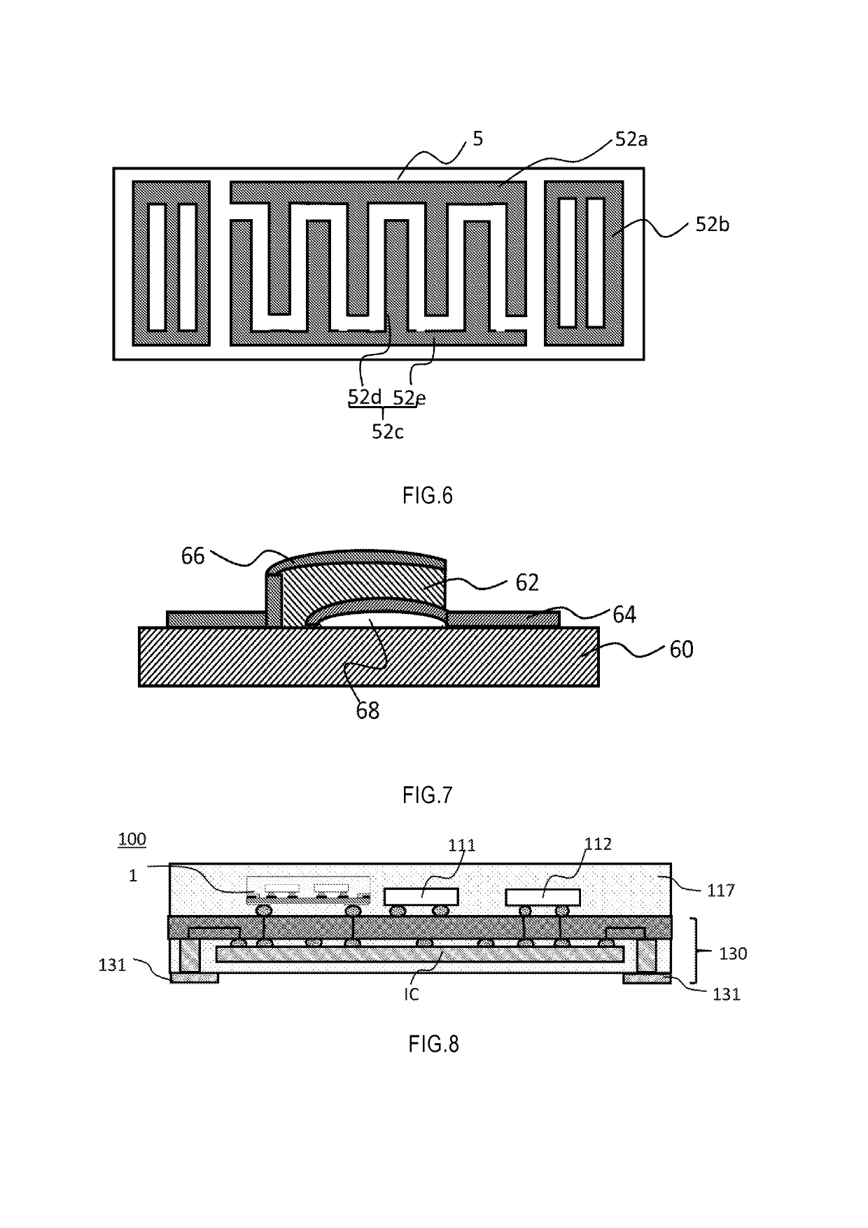

FIG. 7 is a cross-sectional view showing an example in which the elastic wave element 52 is a piezoelectric thin-film resonator.

As shown in FIG. 7, a piezoelectric film 62 is provided on a chip substrate 60. The piezoelectric film 62 is sandwiched between a lower electrode 64 and an upper electrode 66. A cavity 68 is formed between the lower electrode 64 and the chip substrate 60. The lower electrode 64 and the upper electrode 66 excite an elastic wave of a thickness-extensional vibration mode in the piezoelectric film 62.

The chip substrate 60 may be a semiconductor substrate such as silicon, or an insulating substrate such as sapphire, alumina, spinel, or glass. The piezoelectric film 62 may be made of, for example, aluminum nitride.

The lower electrode 64 and the upper electrode 66 may be made of a metal material such as ruthenium.

The elastic wave element 52 may, as necessary, be applied to a multimode filter, a ladder filter, or the like, to obtain the desired band-pass filter characteristics.

According to one embodiment of the present invention described above, it is possible to provide an elastic wave device having good heat dissipation, excellent adhesion between the sealing portion and the wiring substrate, and excellent characteristics in which coupling between a metal pattern that allows passage of electric signals in a desired frequency band and a metal pattern that does not allow passage is unlikely to occur, while also being able to control the amount of sealing resin penetrating between the wiring substrate and the device chip.

### Embodiment 2

Embodiment 2 of another form of the present invention will be described below.

FIG. 8 is a cross-sectional view of a module 100 according to Embodiment 2 of the present invention.

As shown in FIG. 8, the elastic wave device 1 is mounted on a main surface of a wiring substrate 130. The elastic wave device 1 may be, for example, an unillustrated dual-channel filter composed of a first band-pass filter BPF1 and a second band-pass filter BPF2.

The wiring substrate 130 is provided with a plurality of external connection terminals 131. The plurality of external connection terminals 131 are arranged to be mounted on a main board of a predetermined mobile communication terminal.

On the main surface of the wiring substrate 130, a first inductor element 111 and a second inductor element 112 are mounted to achieve impedance matching. The module 100 packages a plurality of electronic components including the elastic wave device 1 by means of a sealing portion 117.

An integrated circuit component IC is mounted inside the wiring substrate 130. The integrated circuit component IC (not shown in the figure) includes a switch circuit SW, a first low-noise amplifier LNA1, and a second low-noise amplifier LNA2.

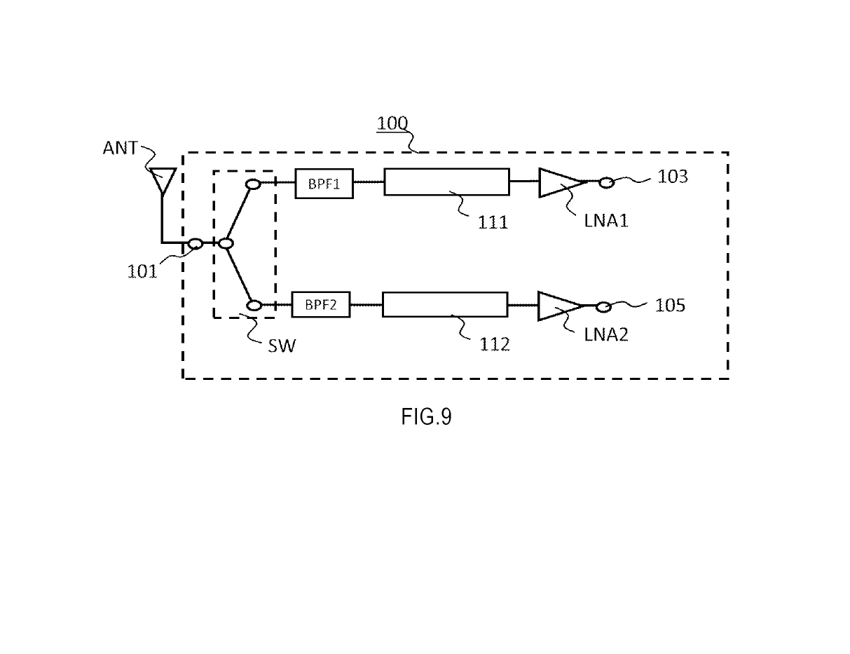

FIG. 9 is a schematic diagram illustrating an outline of the circuit configuration of the module 100.

As shown in FIG. 9, a common input terminal 101 (external connection terminal 131) of the module 100 is connected to an antenna terminal ANT. The first output terminal 103 and the second output terminal 105 (external connection terminals 131) are connected to an unillustrated signal processing circuit.

Through the switch circuit SW, a signal input from the common input terminal 101 is switched to a signal passing through the first band-pass filter BPF1 or a signal passing through the second band-pass filter BPF2.

A signal passing through the first band-pass filter BPF1 is impedance matched by the first inductor element 111, amplified by the first low-noise amplifier LNA1, and then output from the first output terminal 103. Alternatively, when the first band-pass filter BPF1 is used as a transmission filter, the first output terminal 103 may function as an input terminal. In this case, the signal amplified by the first low-noise amplifier LNA1 and impedance matched by the first inductor element 111 is transmitted via the first band-pass filter BPF1 and emitted from the antenna terminal.

A signal passing through the second band-pass filter BPF2 is impedance matched by the second inductor element 112, amplified by the second low-noise amplifier LNA2, and then output from the second output terminal 105. Alternatively, when the second band-pass filter BPF2 is used as a transmission filter, the second output terminal 105 may function as an input terminal. In this case, the signal amplified by the second low-noise amplifier LNA2 and impedance matched by the second inductor element 112 is transmitted via the second band-pass filter BPF2 and emitted from the antenna terminal.

The remaining structure is the same as described in Embodiment 1, and thus description thereof is omitted.

According to the embodiment of the present invention described above, it is possible to provide a module including an elastic wave device having excellent characteristics, such as good heat dissipation, excellent adhesion between the sealing portion and the wiring substrate, and in which coupling between a metal pattern that allows passage of electric signals in a desired frequency band and a metal pattern that does not allow passage is unlikely to occur. Of course, the present invention is not limited to the embodiments described above, but rather encompasses all embodiments capable of achieving the objectives of the invention. It should be understood that the present invention includes all implementations that achieve the objectives described herein, and is not restricted solely to the specific embodiments disclosed.

Although various aspects of some embodiments have been described, it will be readily apparent to those skilled in the art that various modifications, improvements, and enhancements may be made. Such modifications, improvements, and enhancements are intended to be part of the invention and fall within the scope of this disclosure.

It should be understood that the embodiments of the methods and devices described herein are not limited to the configurations and arrangements illustrated or described above. The methods and devices may be realized in other forms and may be implemented or carried out in various ways.

The specific examples provided are for illustrative purposes only and are not intended to be limiting in any way.

The expressions and terms used in this disclosure are for the purpose of illustration and should not be construed as limiting. Terms such as “comprise,” “include,” “have,” “contain,” and variations thereof are intended to include the items listed thereafter as well as equivalents and additional items.

References to “or” are intended to be inclusive, meaning that any of the listed terms may apply individually, in combination, or collectively.

Directional expressions such as front, back, top, bottom, left, right, vertical, horizontal, inside, and outside are used merely for the sake of descriptive convenience. Such expressions do not restrict the components of the invention to any particular spatial position or orientation. Accordingly, the above descriptions and drawings are merely illustrative in nature.

What is claimed is:

1. An elastic wave device, comprising:
a wiring substrate;
a device chip mounted on the wiring substrate via a plurality of bumps, the device chip having a resonator;
a metal pattern formed in an outer edge portion of the wiring substrate;
a plurality of bump pads formed on the wiring substrate and including an antenna pad, a transmission pad, a reception pad, and a ground pad;
a solder resist layer bonded to both the metal pattern and the wiring substrate;
a sealing portion disposed on the wiring substrate and penetrating between the wiring substrate and the device chip to hermetically seal the device chip;
wherein the solder resist layer is bonded to the sealing portion.

2. The elastic wave device according to claim 1, wherein a thermal conductivity of the solder resist layer is 1.0 W/m·K or more.

3. The elastic wave device according to claim 1, wherein the metal pattern has a concave–convex shaped portion or a serrated shaped portion.

4. The elastic wave device according to claim 3, wherein the metal pattern near the device chip including the resonator includes:
a region wherein a tip direction of the concave–convex shaped portion or the serrated shaped portion is oriented toward the outer edge of the wiring substrate; and
a region wherein a tip direction of the concave–convex shaped portion or the serrated shaped portion is oriented toward the center of the wiring substrate.

5. The elastic wave device according to claim 3, wherein in a peripheral region of the antenna pad, the transmission pad, or the reception pad, the tip direction of the concave–convex shaped portion or the serrated shaped portion is oriented toward the center of the wiring substrate.

6. The elastic wave device according to claim 3, wherein the wiring substrate has a rectangular structure with long sides and short sides, and, in a region between two bump pads arranged along at least one short side direction, in the metal pattern located near the device chip provided with the resonator, a length of a region in which the tip direction of the concave–convex shaped portion or the serrated shaped portion is oriented toward the outer edge of the wiring substrate is greater than a length of a region in which the tip direction is oriented toward the center of the wiring substrate.

7. The elastic wave device according to claim 3, wherein the wiring substrate has a rectangular structure with long sides and short sides, and, in two or more regions between bump pads formed by arrangement of three or more bump pads along at least one long side direction, there exist the following two types of regions:
a first type of bump pad interval region in which, in the metal pattern located near the device chip provided with the resonator, a length of a region where the tip direction of the concave–convex shaped portion or the serrated shaped portion is oriented toward the outer edge of the wiring substrate is greater than a length of a region where the tip direction is oriented toward the center of the wiring substrate; and
a second type of bump pad interval region in which, in the metal pattern located near the device chip provided with the resonator, a length of a region where the tip direction of the concave–convex shaped portion or the serrated shaped portion is oriented toward the outer edge of the wiring substrate is less than a length of a region where the tip direction is oriented toward the center of the wiring substrate.

8. The elastic wave device according to claim 3, wherein the wiring substrate has a rectangular structure with long sides and short sides, and, in two or more regions between bump pads formed by arrangement of three or more bump pads along at least one long side direction, there exist two consecutive bump pad interval regions in which, in the metal pattern located near the device chip provided with the resonator, a length of a region where the tip direction of the concave–convex shaped portion or the serrated shaped portion is oriented toward the outer edge of the wiring substrate is greater than a length of a region where the tip direction is oriented toward the center of the wiring substrate, and the bump pad formed between the two consecutive regions is a ground pad.

9. The elastic wave device according to claim 1, wherein a boundary between a region in which the solder resist layer is bonded to the wiring substrate and a region where the sealing portion is bonded to the metal pattern has a concave–convex or serrated shape.

10. The elastic wave device according to claim 9, wherein the solder resist layer extends into concave portions of the metal pattern in the concave–convex shaped region.

11. The elastic wave device according to claim 3, wherein the solder resist layer extends into valley portions of the metal pattern in the serrated shaped portion region.

12. The elastic wave device according to claim 3, wherein resonators disposed on the device chip adjacent to a region wherein a tip direction of the concave-convex or serrated shaped portion is oriented toward the center of the wiring substrate are positioned distal to an outer edge of the device chip; and resonators disposed on the device chip adjacent to a region wherein a tip direction of the concave-convex or serrated shaped portion is oriented toward an outer edge of the wiring substrate are positioned proximal to the outer edge of the device chip.

13. The elastic wave device according to claim 1, wherein the metal pattern includes pattern portions having an intermittent structure.

14. The elastic wave device according to claim 1, wherein the ground pad is electrically connected to the metal pattern.

15. The elastic wave device according to claim 1, wherein the sealing portion is bonded to both the wiring substrate and the metal pattern.

16. The elastic wave device according to claim 1, wherein the solder resist layer exhibits higher adhesion to the metal pattern than the sealing portion.

17. The elastic wave device according to claim 1, wherein a distance between the solder resist layer and the device chip is maintained in a range of 50 μm to 100 μm.

18. The elastic wave device according to claim 1, wherein at least a part of the solder resist layer is subjected to roughening treatment.

19. The elastic wave device according to claim 1, wherein the solder resist layer is formed from a material having a dielectric constant in a range of 2.0 to 3.0 at a frequency of 10 GHz.

20. A module, comprising an elastic wave device according to claim 1.
